(19) United States
(12) Patent Application Publication
(10) Pub. No.: US 2008/0108212 A1
(43) Pub. Date: May 8, 2008

(54) HIGH VOLTAGE VERTICALLY ORIENTED EEPROM DEVICE

(75) Inventors: Thomas S. Moss, Colorado Springs, CO (US); Lee A. Bowman, Colorado Springs, CO (US); Gayle W. Miller, Colorado Springs, CO (US); Stefan Schwantes, Heilbronn (DE)

Correspondence Address: SCHNECK & SCHNECK, P.O. BOX 2-E, SAN JOSE, CA, 95109-0005, US

(73) Assignee: ATMEL CORPORATION, San Jose, CA (US)

(21) Appl. No.: 11/550,964

(22) Filed: Oct. 19, 2006

(51) Int. Cl. H01L 21/3205; H01L 21/4763

(52) U.S. Cl. 438/587

(57) ABSTRACT

Apparatus and a method for adding non-volatile memory cells with trench-filled vertical gates to conventional MOSFET surface devices that have their drain and source regions horizontally positioned near the top surface of a substrate. A surface MOSFET device is used as a structural platform to which is added a vertical trench-filled polysilicon gate and a word line region using a small number of additional mask layers and fabrication process modifications. A vertical trench filled polysilicon gate is formed in a deep trench in a lower region of the substrate and adjacent to a MOSFET body portion of the substrate. The vertical trench-filled polysilicon gate in the deep trench is isolated by dielectric material from the body portion of the MOSFET and from a word line region that is formed in the lower region of the substrate.

### TECHNICAL FIELD

The present invention relates to a vertical EEPROM that combines a surface MOSFET with deeply buried trench.

### BACKGROUND

Vertically oriented non-volatile memory cells are known. For example, U.S. Pat. No. 6,921,696 to Rudeck discloses a non-volatile memory cell that has a vertically oriented transistor having a vertical floating gate and a vertical control gate. A vertical channel region is formed with a source region that is formed in one plane and a drain region that is formed in a plane above the source region. U.S. Pat. No. 6,878,991 to Forbes describes an EEPROM memory device that provides vertical floating gate memory cells having N+ doped regions provided respectively at the top and bottom of a vertical trench to form the source and to the drain regions for a vertically oriented floating gate memory cell. These types of non-volatile memory devices are fabricated with a vertical orientation such that the drain and source regions are at different levels and the channel region is vertically oriented.

Many conventional MOSFET devices are so-called surface devices that are fabricated on a semiconductor wafer with their drain and source regions at the same level near the top surface of a substrate and with their channels horizontally oriented. Adding a small number of non-volatile EEPROM cells with floating gates to such a wafer requires a number of additional mask layers and fabrication process modifications.

### SUMMARY OF THE INVENTION

The present invention provides for adding non-volatile memory cells with trench-filled polysilicon gate to conventional power MOSFET surface devices which have their drain and source regions at the same level near the top surface of a substrates and with their channels horizontally oriented. The present invention provides an added buried vertical trench-filled polysilicon gate using a small number of additional mask layers and fabrication process modifications.

The present invention provides an EEPROM device structures that includes a substrate with a surface MOSFET formed in an upper region of the substrate. The surface MOSFET has a body portion. A vertical trench-filled polysilicon gate is formed in a trench in a lower region of the substrate and adjacent to the MOSFET body portion of the substrate. The vertical trench-filled polysilicon gate is isolated by dielectric material from the body portion of the MOSFET with one side of the vertical trench-filled polysilicon gate being adjacent to the MOSFET body portion of the substrate. A “word line” region is formed in the lower region of the substrate adjacent to another side of the vertical trench-filled polysilicon gate and isolated from the vertical trench-filled polysilicon gate by dielectric material.

In one embodiment of the invention, the MOSFET body portion is a P-doped material, the MOSFET source and drain regions are diffused N+ material, and the memory word line, region is a P-type silicon material. A buried oxide layer is formed beneath the substrate, it which is formed the trench containing the vertical trench-filled polysilicon gate. Respective electrical contacts are connected to the MOSFET body portion, the MOSFET source region, the MOSFET drain, the MOSFET gate region, and the “word line” region.

The present invention provides an EEPROM device structure that includes a substrate and a surface MOSFET formed in an upper region of the substrate. The surface MOSFET includes a MOSFET body portion of the substrate, a MOSFET source region that is formed in the MOSFET body portion of the substrate, a MOSFET drain region that is formed in the MOSFET body portion of the substrate, a MOSFET channel region that is formed between the MOSFET source and drain regions in the MOSFET body portion of the substrate, and a MOSFET gate region that is formed over the MOSFET channel region and that is insulated from the MOSFET channel region by a gate dielectric layer.

The EEPROM device structure further includes a deep buried vertical trench-filled polysilicon gate that is formed in a trench in a lower region of the substrate adjacent to the MOSFET body portion of the substrate. The vertical trench-filled polysilicon gate is isolated by dielectric material from the MOSFET body portion of the substrate. One side of the vertical trench-filled polysilicon gate is adjacent to the MOSFET body portion of the substrate.

The EEPROM device structure also includes a memory “word line” region that is formed in the lower region of the substrate adjacent to another side of the vertical trench-felled polysilicon gate and isolated from the vertical trench-filled polysilicon gate by dielectric material.

In one embodiment of the invention the MOSFET body portion is a P-doped material, the MOSFET source and drain regions are diffused N+ material, and the memory word line region is a P-type silicon material.

In another embodiment of the invention, a buried oxide layer is formed beneath the substrate over which is the trench containing the vertical trench-filled polysilicon gate.

The EEPROM device structure includes respective electrical contacts that are connected to the MOSFET body portion, the MOSFET source region, the MOSFET drain, the MOSFET gate region, and the “word line” region.

In another embodiment of the invention, a dual EEPROM device structure is provided that includes a substrate and a first and a second surface MOSFET formed in an upper region of the substrate. Each of the surface MOSFETs includes: a MOSFET body portion of the substrate, a MOSFET source region that is formed in the MOSFET body portion of the substrate, a MOSFET drain region that is formed in the MOSFET body portion of the substrate, a MOSFET channel region that is formed between the MOSFET source and drain regions in the MOSFET body portion of the substrate, and a MOSFET gate region that is formed over the MOSFET channel region and that is insulated from the MOSFET channel region by a gate dielectric layer. For the dual EEPROM device structure, a first and a second vertical trench-filled polysilicon gate are each formed in a respective trench in a lower region of the substrate. Each trench is adjacent to a respective MOSFET body portion of the substrate and each of the vertical trench-filled polysilicon gates is isolated by dielectric material from the respective MOSFET body. One side of each of the vertical trench-filled polysilicon gate is adjacent to the respective MOSFET body portion of one of the surface MOSFETS. A commonly shared memory “word line” region is formed in the lower region of the substrate adjacent to another side of each of the vertical trench-filled polysilicon gates and isolated from the vertical trench-filled polysilicon gates by dielectric material.

A method of fabricating an EEPROM device includes the steps of: forming a trench in a lower region of a substrate; lining the trench with a dielectric material; filling the lined trench with polysilicon material to provide a vertical trench-filled polysilicon gate; forming a surface MOSFET in an upper region of a body portion of the substrate; and forming a “word line” region in the lower region of the substrate adjacent to another side of the vertical trench-filled polysilicon gate and isolated from the vertical polysilicon floating gate by dielectric material lining the trench.

The method further includes the steps of doping the MOSFET body portion to provide a P-doped body portion, diffusing N+material into the MOSFET source and drain regions, and doping the memory word line region to provide a P-type silicon material.

The method includes forming a buried oxide layer over which is formed the trench containing the vertical trench-filled polysilicon gate. Respective electrical contacts are connected to the MOSFET body portion, the MOSFET source region, the MOSFET drain, the MOSFET gate region, and the “word line” region.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 is top view (with a top oxide layer removed for clarity) showing two surface MOSFET transistors that are configurable as EEPROMS by the addition of buried vertical trench-filled polysilicon gates according to the present invention.

FIG. 2 is a sectional view taken along section line 2-2 of FIG. 1 with the top oxide layer in place and showing a central word line that is flanked on each side by a buried vertical trench-filled polysilicon gate.

FIG. 3 is a sectional view taken along section line 4-4 of FIG. 1 with the top oxide in place and showing an external connection to the central word line.

FIG. 4 is a sectional view taken along section line 4-4 of FIG. 1 with the top oxide in place and showing one of the surface MOSFET memory transistors and its external connections along with a buried vertical floating gate.

FIG. 5 is a chart illustrating various features, dimensions, and voltages for a device according to the present invention.

FIG. 6 is a top view of an 80 volt high-voltage neighbor power device positioned adjacent to a low voltage NMOS device.

FIG. 7 is a cross-sectional view taken along section line 6-6 of FIG. 5 illustrating a depletion layer formed in a p-well body of the low voltage NMOS device caused by the high-voltage neighbor power device.

FIG. 8 shows graphs of drain leakage currents for 5 volt PMOS and NMOS low voltage devices as a function of the high voltage on a high-voltage neighbor power device.

FIG. 9 shows graphs of drain leakage current (before and after high-voltage stress) for 5 volt PMOS and NMOS low voltage devices as a function of the high voltage on a high-voltage neighbor power device.

FIG. 10 shows graphs of drain leakage currents for thicker oxide linings in the trench.

FIG. 11 are graphs of drain leakage current for three drain voltages as a function of the high voltage on a high-voltage neighbor power device.

### DETAILED DESCRIPTION

The present invention allows non-volatile memory devices to be added to integrated circuits and to power MOS integrated circuits. With a minimal addition of several mask layers, a non-volatile memory can be merged with or embedded in conventional MOSFET or high-power integrated circuits by adding a deeply buried vertical trench-filled polysilicon gate to a surface MOSFET device.

An object of the present invention is to take a high-voltage power device technology, with full dielectric isolation, and quickly and inexpensively add an EEPROM-like device, with no or minimal extra process steps and with no or minimal modification to the process. The added memory devices would be sufficient to store, for example, a few hundred bits of a program code or an identification code.

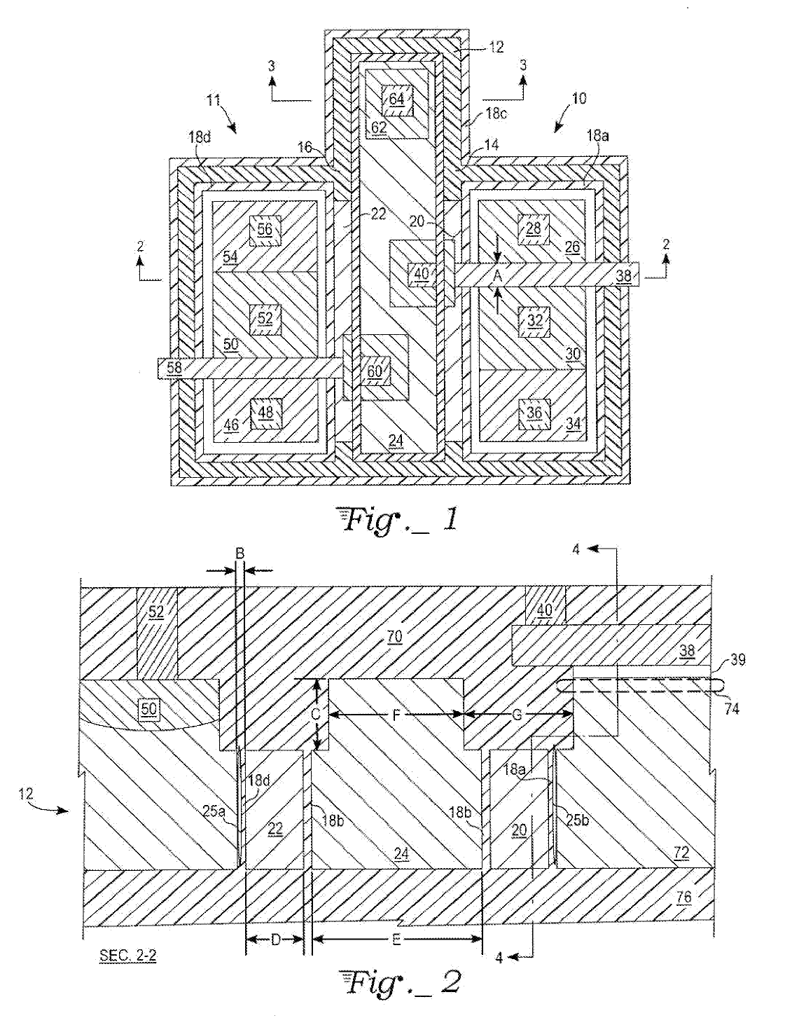

With reference to FIGS. 1-4, one embodiment of the present invention is illustrated as a dual EEPROM configuration. Each one of a pair of EEPROM device structures 10, 11 according to the present invention utilizes a conventional power device surface MOSFET device structure that is formed at the top surface of a substrate 12. To form an EEPROM structure with a vertical trench-filled polysilicon gate, the conventional top-surface MOSFET device structures 10, 11 are each supplemented with a respective one of a pair of a deeply buried vertical trench-filled polysilicon gates 20, 22. Each of the deeply buried vertical trench-filled polysilicon gates 20, 22 is isolated in a portion of a deep trench 14 that is formed in the lower region of the substrate 12 and lined with a dielectric material. A buried word line region 24 is also formed in the lower region of the substrate 12 adjacent to the vertical trench-filled polysilicon gate.

FIG. 1 shows the first surface MOSFET transistor 10 and the second surface MOSFET transistor 11 with their top oxide layers removed. The deep trench 14 is formed around the MOSFET transistors 10, 11 and the buried word line region 24. Each side of the trench 12 is lined with a respective layer of oxide 18a, 18b, 18c, 18d. Two portions of the oxide-lined trench 12 are then tilled with polysilicon to provide the respective vertical trench-filled polysilicon gates 20, 22.

For the surface MOSFET transistor 10, a heavily doped N diffusion layer 26 forms a MOSFET drain region that is provided with a conductive via 28 for external connection. Another heavily doped N diffusion layer 30 forms a MOSFET source region that is provided with a conductive via 32 for external connection. A heavily doped P diffusion layer 34 is diffused into the body of the MOSFET transistor 10 and is provided with a conductive via 36 for external connection. A conventional gate 38 for the MOSFET is formed as a conductive strips that overlies a channel region formed near the top surface of the substrate. A thin dielectric layer 39 is placed between the gate 38 and the channel region. A conductive via 40 is provided for external connection to the gate 38.

In a similar manner, the other surface MOSFET transistor 11 has a heavily doped N diffusion layer 46 that forms a MOSFET drain region that is provided with a conductive via 48 for external connection. Another heavily doped N diffusion layer 50 forms a MOSFET source region that is provided with a conductive via 52 for external connection. A heavily doped P diffusion layer 54 is diffused into the body of the MOSFET transistor 11 and is provided with a conductive via 56 for external connection. A conventional gate for the MOSFET is formed as a conductive strip 58 that overlies another channel region formed near the top surface of the substrate. A thin dielectric layer is placed between the gate 58 and the channel region. A conductive via 60 is provided for external connection to the gate 58. FIG. 1 also shows a heavy P-type or N-type diffusion area 62 that is diffused into a central word line region that is also used for programming an EEPROM device. A conductive via 64 provides external connection.

FIG. 2 is a sectional view showing a mid-plane view of the surface MOSFET transistor 10. In this view is shown in place a top oxide layer 70, through which extends the conductive via 40 for the gate 38. Beneath the gate dielectric layer 39 is shown a body portion 72 of the first surface MOSFET transistor 10. A channel region 74 for the MOSFET transistor 10 is located beneath the thin gate dielectric layer 39. The body portion 72 is part of the P-doped substrate 12 that is formed over a buried oxide layer 76 in the lower part of the substrate. Also extending through the top oxide layer 70 is the conductive via 52 that is connected to the heavily doped N diffusion layer 50 that forms the source of the second MOSFET transistor 11.

FIG. 2 also shows a central word line region 24 that is flanked on each side by respective buried vertical trench-filled polysilicon gates 20, 22 that are each formed in one respective portion of the vertically extending deep trench 14 formed in the substrate 12. The vertically oriented trench-filled polysilicon gates 20, 22 are isolated from the word line region 24 by dielectric material from corresponding portions of the oxide layer 18b. The vertically oriented trench-filled polysilicon gates 20, 22 are also isolated from the body portions of the MOSFET transistors 10, 11 by dielectric material from corresponding portions of the oxide layers 18a and 18d.

The trench-tilled polysilicon is undoped. It is believed that the structure of the present invention stored charge that modifies the conductivity state, or leakage characteristics, of the MOSFET devices adjacent to the trench-fill polysilicon. This means that the trench-fill polysilicon may function minimally as a Floating gate. It is believed that a main function of the trench-fill polysilicon is probably as a high-K dielectric material which increases the effect of the neighboring voltage on the sidewall of the MOSFET device functioning as a memory device. Silicon diode has a relative dielectric constant of about 3.9 and silicon is about 11.9. The high-K material reduces the electrical width of the trench dielectric and silicon composite sandwich. It is believed that controlling charge may be stored in the trench dielectric regions 25a, 25b, between the trench-fill polysilicon and the body of the adjacent MOSFET regions 18a and 18d.

FIG. 3 illustrates the top oxide layer 70 in place and shows the external connection to the central word line region 24 through a heavy P-type or N-type diffusion area 62 and the conductive via 64. Appropriate programming voltages applied between the word line region and the gate 38 are used for programming and erasing the EEPROM device.

An appropriate bias voltage applied to the gate 38 through the conductive via 40 can be used to adjust the memory properties ad the operation of EEPROM devices provided according to the present invention.

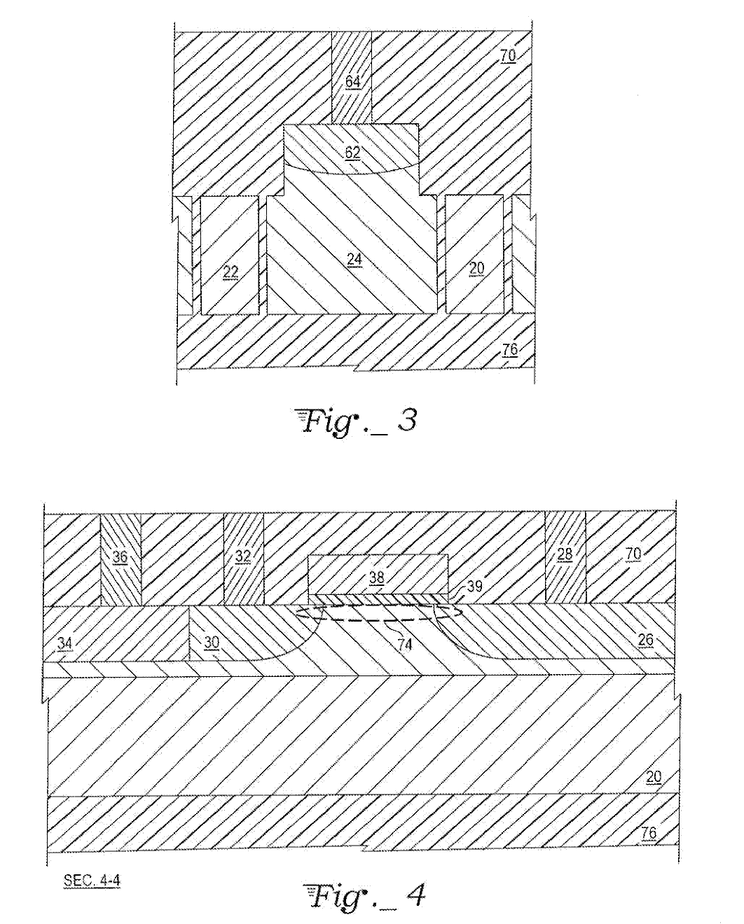

FIG. 4 also shows the top oxide layer 70 in place over the surface MOSFET memory transistor 10. The heavily doped N diffusion layer 26 forms the MOSFET drain region that is provided with the conductive via 28 for external connection. The heavily doped N diffusion layer 30 forms the source region that is provided with the conductive via 32 for external connection. The heavily doped P diffusion layer 34 is diffused into the body of the MOSFET transistor 10 and is provided with a conductive via 36 for external connection. The gate 38 and the thin gate dielectric layer 39 are shown overlying the channel region 74 of the MOSFET 10. The buried trench-filled polysilicon gate 20 is adjacent to the body of the MOSFET transistor 10. The word line region 24 serves both EEPROM devices for both programming and erasing.

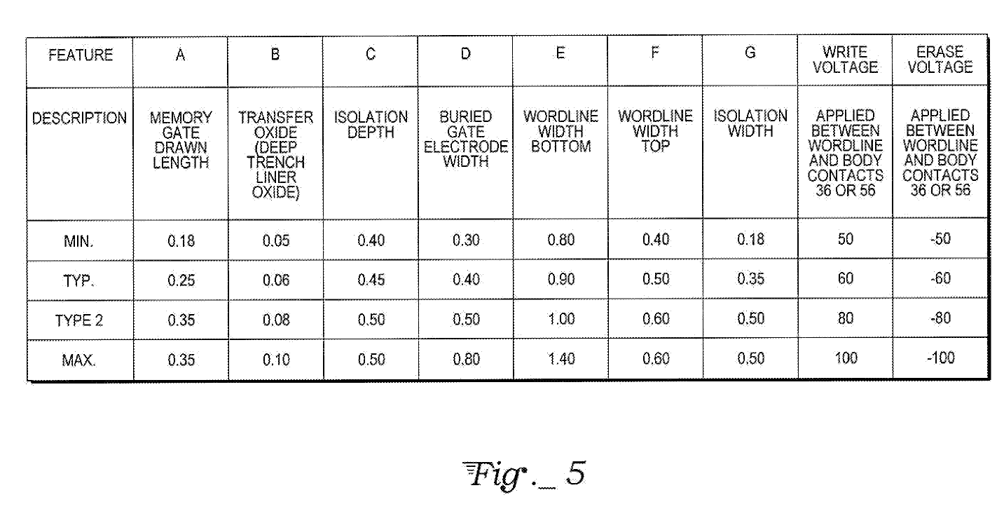

FIG. 5 is a charge that illustrates various feature approximate dimensions and voltages or the device structure of FIGS. 1-4. Note that these dimensions and voltages are illustrative and the present invention is not limited to those values. Minimum, two typical, and maximum values are provided. The dimensions are in reference to FIGS. 1 and 2 are in microns and the voltages are in volts. Feature A is the memory gate drawn length and ranges between 0.18 and 0.35 microns. Feature B is the transfer oxide thickness and ranges between 0.05 and 0.10 microns. Feature C is the isolation depth and ranges between 0.40 and 0.50 microns. Feature D is the buried trench-fill polysilicon gate width and varies between 0.30 and 0.80 microns. Feature E is the wordline width bottom and varies between 0.80 and 1.40 microns. Feature F is the wordline width top and varies between 0.40 and 0.60 microns. Feature G is the isolation width and varies between 0.18 and 0.50 microns. The write voltage varies between positive 50 and 100 volts. The erase voltage varies between minus 50 and 100 volts.

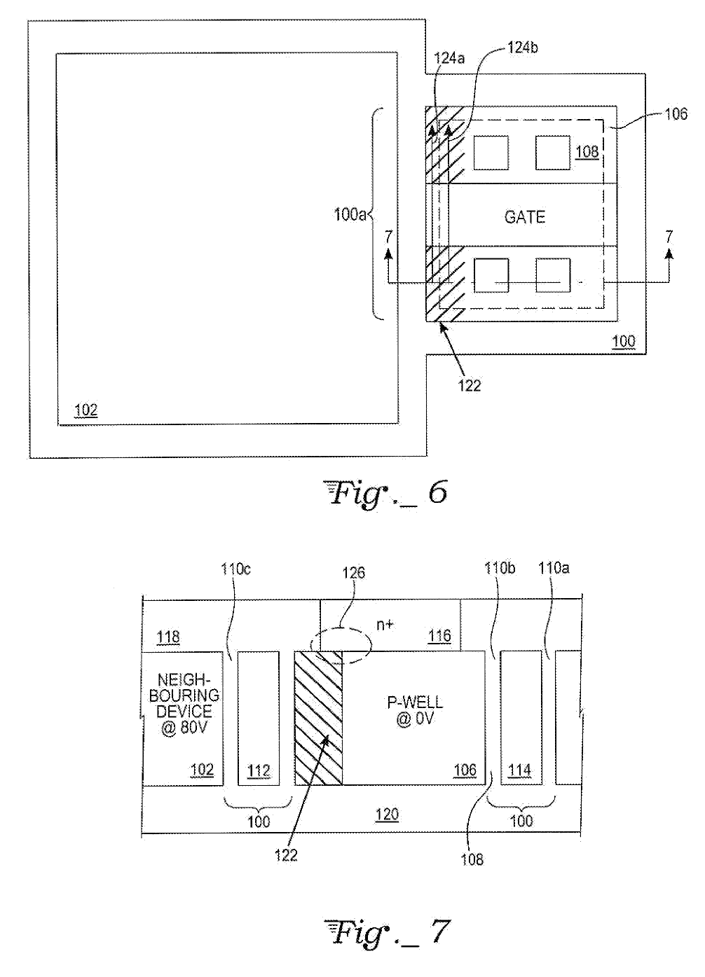

With reference to FIG. 6 and FIG. 7, various portions of a deep trench 100 form two boxes, one of which surrounds a body 102 of a PDMOS 80-volt high-voltage power device and the other of which surrounds a P-well body 106 of a 5-volt NMOS device 108. FIG. 7 shows that each side of various parts of the trench 100 is lined with one of a number of thin layers 110a, 110b, 110c of dielectric materials. The trench is filled with polysilicon. As shown in FIG. 6, one portion 100a of the trench 100 is filled with polysilicon to form a floating gate 112 for an EEPROM device as described herein above. An n+ doped region 116, forming a source or drain region, overlies the P-well body 106 of the 5-volt NMOS device 108. A top oxide layer 118 overlies the 5-volt NMOS device 108 and a buried oxide layer 120 is beneath the trench 100 and the device bodies 102, 106.

If the body 102 of the high-voltage power device 104 is at 80 volts and the body 106 of the NMOS device is at 0 volts, the resultant electric field produces a depletion zone 122 in the body 108 of the NMOS device. The depletion zone 122 provides parasitic leakage paths 124a, 124b. The depletion zone 122 causes punch through between a source and drain of the NMOS device 108 in a punch through zone 126 formed at the junction of the n+ doped region 116 and the depletion region 122.

FIG. 8 shows drain leakage currents for 5 jolt PMOS and NMOS low voltage devices as a function of the high voltage on the high-voltage power device.

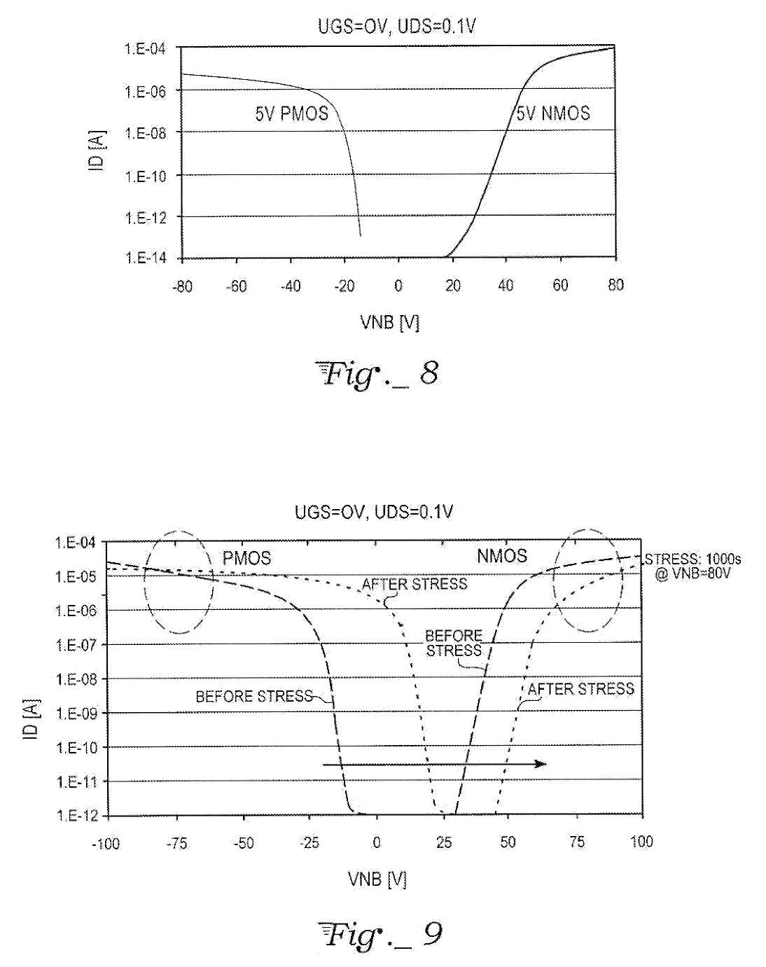

FIG. 9 shows before and after drain leakage currents for a low voltage PMOS device and on a low voltage NMOS device as a function of the high voltage on a high-voltage neighbor power device after an 80-volt stress for 1000 seconds. Electrons are trapped, which causes a shift in the threshold voltage of the leakage currents. The low-voltage PMOS device will cease to function after this type of stress.

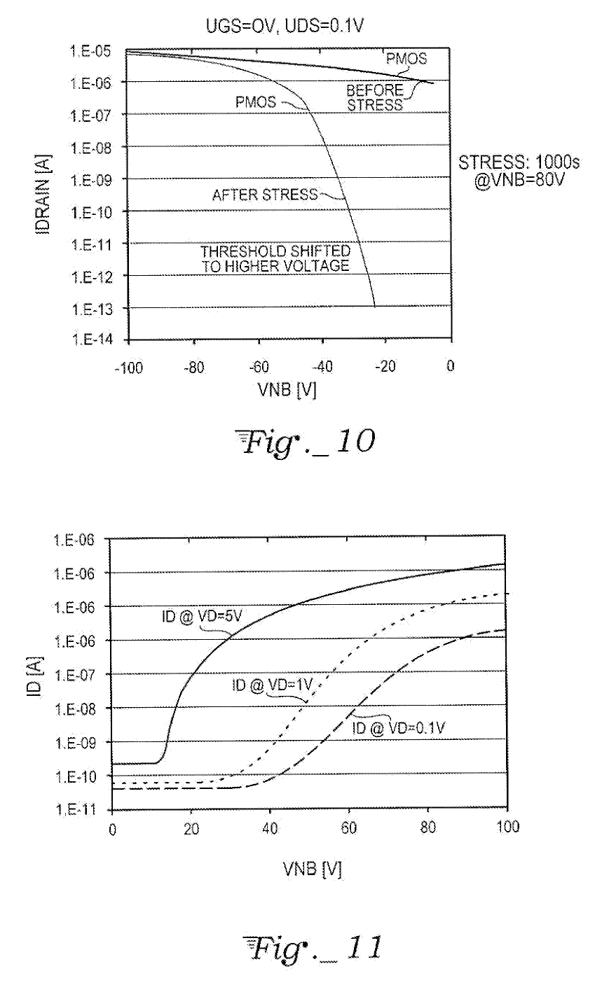

FIG. 10 illustrates that forming 50 nm thicker oxide linings in the trench 100 cannot avoid leakage current and electron trapping.

FIG. 11 are graphs of drain leakage current as a function of the high stress voltage for three different drain voltages on low voltage NMOS device, illustrating that a leakage mechanism also affects other types of devices.

The performance of an EEPROM-like device provided by the present invention may be restricted regarding, for example, write time. Controlling charge is stored for example, in the trench dielectric material between the trench-filled polysilicon gates and the adjacent body portions of the MOSFETS. This may result in limited cycling performance. High voltages for inviting function are available in a high-voltage power device.

The foregoing description of a specific embodiment of the present invention has been presented for purposes of illustration and description. It is not intended to be exhaustive or to limit the invention to the precise forms disclosed, and obviously many modifications and variations are possible in light of the above teaching. The embodiment was chosen and described in order to best explain the principles of the invention and its practical application, to thereby enable others skilled in the art to best utilize the invention and various embodiments with various modifications as are suited to the particular use contemplated. It is intended that the scope of the invention be defined by the claims appended hereto and their equivalents.

1. An EEPROM device structure, comprising:
a semiconductor substrate body having a surface MOSFET with a body portion and being formed in an upper region of the substrate body;
a vertical trench-filled polysilicon floating gate that is formed in a trench in a lower region of the substrate body adjacent to a current path of said surface MOSFET body portion, said vertical trench-filled polysilicon gate being isolated by dielectric material from the body portion of said surface MOSFET, wherein one side of the vertical trench-filled polysilicon gate is adjacent to the surface MOSFET body portion of said substrate; and
a memory word line region that is formed in the lower region of the substrate body adjacent to another side of the vertical trench-filled polysilicon gate and that is isolated from the vertical trench-filled polysilicon gate by dielectric material, whereby leakage of the surface MOSFET from the current path is stored using the polysilicon floating gate.

2. The EEPROM device structure of claim 1 wherein the substrate body is formed with a P-doped material, the MOSFET having source and drain regions that are formed of diffused N+ material, and the memory word line region is formed with a P-type silicon material.

3. The EEPROM device structure of claim 1 including a buried oxide layer formed beneath the substrate.

4. The EEPROM device structure of claim 1 including respective electrical contacts that are connected for providing external contacts to the MOSFET body portion, to a MOSFET source region, to a MOSFET drain, to a MOSFET gate region, and to the memory word line region.

5. An EEPROM device structure, comprising:
a semiconductor substrate body;
a surface MOSFET body portion formed in an upper region of the substrate body, the MOSFET body portion having:
a MOSFET source region;
a MOSFET drain region;
a MOSFET channel region that is formed between the MOSFET source and drain regions; and
a MOSFET gate region that is formed over said MOSFET channel region and that is insulated from said MOSFET channel region by a gate dielectric layer;
a buried vertical trench-filled polysilicon floating gate that is formed in a trench in a lower region of the substrate body adjacent to a current path in said MOSFET body portion of said substrate body, said vertical trench-filled polysilicon gate being isolated by dielectric material from the MOSFET body portion of said substrate body, wherein one side of the vertical trench-filled polysilicon gate is adjacent to the MOSFET first body portion; and
a memory word line region that is formed in the lower region of the substrate body adjacent to another side of the vertical trench-filled polysilicon floating gate and isolated from the vertical trench-filled polysilicon floating gate by dielectric material, whereby leakage of the surface MOSFET body portion in the current path is stored using the polysilicon floating gate.

6. The EEPROM device structure of claim 5 wherein the source and drain regions of the MOSFET body portion are diffused N+ material, and the memory word line region is a P-type silicon material.

7. The EEPROM device structure of claim 5 including a buried oxide layer formed beneath the substrate.

8. The EEPROM device structure of claim 5 including respective electrical contacts that are connected to the MOSFET body portion, to the MOSFET source region, to the MOSFET drain, to the MOSFET gate region, and to the word line region.

9. A dual EEPROM device structure, comprising:
a semiconductor substrate body;
a first and a second surface MOSFET body portion that are formed in an upper region of the substrate body;
each MOSFET body portion of said substrate body having:
a MOSFET source region that is formed in the MOSFET body portion of said substrate body;
a MOSFET drain region that is formed in the MOSFET body portion of said substrate body;
a MOSFET channel region that is formed between the MOSFET source and drain regions in the MOSFET body portion of said substrate body; and
a MOSFET gate region that is formed over said MOSFET channel region and that is insulated from said MOSFET channel region by a gate dielectric layer;
a first and a second vertical trench-filled polysilicon floating gate that are each formed in a respective trench in a lower region of the substrate body, wherein each trench is adjacent to a current path in a respective MOSFET body portion of the substrate body, each of said vertical trench-filled polysilicon gates being isolated by dielectric material from a respective MOSFET body portion, wherein one side of each of the vertical trench-filled polysilicon floating gate is adjacent to a respective MOSFET body portion; and
a commonly shared memory word line region that is formed in the lower region of the substrate adjacent to another side of each of the vertical trench-filled polysilicon floating gates and that is isolated from the vertical trench-filled polysilicon floating gates by dielectric material, whereby leakage of each surface MOSFET in the current path is stored using a polysilicon floating gate.

10. A method of fabricating an EEPROM device, comprising the steps of:
forming a trench in a lower region of a semiconductor substrate body;
lining said trench with a dielectric material;
filling the lined trench with polysilicon material to form a vertical trench-filled polysilicon floating gate;
forming a surface MOSFET in an upper region in a body portion of the substrate situated along and insulated from the floating gate in an orientation whereby leakage current of the surface MOSFET in a current path can be stored using the polysilicon floating gate; and
forming a word line region in the lower region of the substrate body adjacent to another side of the vertical trench-filled polysilicon floating gate and isolated from the vertical trench-filled polysilicon gate by dielectric material lining the trench.

11. The method of claim 10 including the steps of doping the surface MOSFET body portion to form a P-doped body portion, diffusing N material into the MOSFET source and drain regions, and doping the memory word line region to provide a P-type silicon material.

12. The method of claim 10 including forming a buried oxide layer formed beneath the substrate.

13. The method of claim 10 including forming respective electrical contacts that are connected to the MOSFET body portion, to the MOSFET source region, to the MOSFET drain, to the MOSFET gate region, and to the word line region.

14. An EEPROM device structure, comprising:
a semiconductor substrate body having a surface MOSFET of a first conductivity type in a first body portion and being formed in an upper region of the substrate body;
a vertical trench-filled polysilicon floating gate that is formed in a trench in a lower region of the substrate body and that has a first trench region adjacent to said surface MOSFET first body portion, said vertical trench-filled polysilicon gate being isolated by dielectric material from the first body portion of said surface MOSFET, wherein one side of said first region of the vertical trench-filled polysilicon gate is adjacent to a current path of the surface MOSFET first body portion of said substrate such that leakage of the surface MOSFET from the current path is stored in the polysilicon floating gate;
a memory word line region that is formed in the lower region of the substrate body adjacent to another side of the vertical trench-filled polysilicon gate and that is isolated from the first and second trench regions of the vertical trench-filled polysilicon gate by dielectric material; and
a second body portion of the substrate body adjacent to the first body portion having a second conductivity type, the second body portion adjacent to a second region of the vertical trench-filled polysilicon gate, whereby the first and second body portions of the substrate body together with the word line region control charge storage in the trench-filled polysilicon gate.

15. The EEPROM device structure of claim 14 wherein the second body portion of second conductivity type is formed with a P-doped material, while the MOSFET source and drain regions of first conductivity type are formed of diffused N+ material, and the memory word line region is formed with a P-type silicon material.
